(19) United States
(12) Patent Application Publication
(10) Pub. No.: US 2024/0046000 A1
(43) Pub. Date: Feb. 8, 2024

(54) DEVICE AND PROGRAM FOR THREE-DIMENSIONAL CALCULATION OF RETAINING WALL MODEL

(71) Applicant: SANEI CO., LTD., Hiroshima-shi (JP)

(72) Inventor: Makoto YAMAMOTO, Hiroshima-shi (JP)

(73) Assignee: SANEI CO., LTD., Hiroshima-shi (JP)

(21) Appl. No.: 18/225,949

(22) Filed: Jul. 25, 2023

(30) Foreign Application Priority Data
Aug. 4, 2022 (JP) 2022-125013

(51) Int. Cl. G06F 30/13; G06T 19/20

(52) U.S. Cl. CPC G06F 30/13; G06T 19/20; G06T 2210/21; G06T 2219/2004; G06T 2219/2021

(57) ABSTRACT

The present disclosure allows precise calculation of an end position and a shape change point of a retaining wall in three dimensions. A three-dimensional calculation device for a retaining wall model includes: a slope placement unit that places a slope having a three-dimensional shape on a three-dimensional road model; an input unit that receives an input of an attribute of the retaining wall model; a calculation unit that calculates a three-dimensional intersection line of the slope model placed by the slope placement unit and the retaining wall model that is based on the attribute inputted to the input unit; and a display that displays information on the three-dimensional intersection line calculated by the calculation unit.

### CROSS-REFERENCE TO RELATED APPLICATION

This application claims priority to Japanese Patent Application No. 2022-125013 filed on Aug. 4, 2022, the entire disclosure of which is incorporated by reference herein.

### BACKGROUND

The present disclosure relates to a device and program for three-dimensional calculation of a retaining wall model used for road design, for example.

In recent years, three-dimensional CAD systems have been introduced in various fields to perform design work. Three-dimensional CAD systems have also been introduced in the field of road design. For example, Japanese Patent No. 6848038 discloses a device for automatically placing a retaining wall model on a three-dimensional road model, and Japanese Patent No. 6848031 discloses a device for checking retaining wall stability that executes processing for checking the stability of a retaining wall on a three-dimensional road model.

The automatic placement device of Japanese Patent No. 6848038 is configured to specify a section for placing a retaining wall based on a distance between a center line and a slope on a three-dimensional road model, set a reference line for the placement of the retaining wall in the specified section, place a candidate retaining wall shape in accordance with the reference line, and then automatically adjust the height of the retaining wall.

The stability check device of Japanese Patent No. 6848031 is configured to receive selection of a retaining wall as a target of the stability check on a three-dimensional road model, execute stability check processing for the target retaining wall, and change the color of the retaining wall on the three-dimensional road model based on the result of the stability check.

### SUMMARY

For calculation of a retaining wall by an existing two-dimensional road design technology, an end position and the height of the retaining wall are calculated from a two-dimensional plane and cross sections, based on information items such as road alignment, a longitudinal grade, a cross grade, and a height of shoulders obtained from road width components, and a ground height. Thus, it has been difficult to accurately determine the end position and height of the retaining wall due to inconsistency of them, making a blueprint inappropriate in some cases.

A recent three-dimensional modeling technology for the road design makes a two-dimensional drawing provided by an existing technology directly into a three-dimensional model, making some parts inconsistent. Specifically, it is common in the civil engineering industry to create two-dimensional cross sections at points given at a specified pitch (e.g., a pitch of five or one meter) and connect the cross sections to create a three-dimensional model. Thus, no cross sections are created at any point between the given points because the cross sections are created only at the specified pitch. A three-dimensional model of the retaining wall is also generated by connecting the sections of the retaining wall taken at points given at a specified pitch, and thus no sections are created at any point between the given points. This means that a point where the shape of the retaining wall changes cannot be obtained between the given points, and the end of the retaining wall cannot be obtained when the end position of the retaining wall does not coincide with any of the given points. The resulting three-dimensional product cannot be satisfactory.

In particular, the retaining wall is mainly made of concrete which increases the construction cost. Thus, it is required to calculate the exact quantities of concrete and other ingredients in the design phase. A method that can meet the requirement is preparing a development of the retaining wall. However, the preparation of the development requires obtainment of more accurate positions of the end and shape change point and height of the retaining wall than in earthworks such as making a slope or a flat embankment. Thus, a device that can perform precise three-dimensional calculation of the retaining wall is required. In the current situation, however, the three-dimensional model is generated merely by connecting the cross sections of the retaining wall taken at the specified pitch as described above, which lacks accuracy.

In view of the foregoing, an object of the present disclosure is to enable precise calculation of an end position and a shape change point of a retaining wall in three dimensions.

In order to achieve the object, an aspect of the present disclosure is directed to a three-dimensional calculation device for a retaining wall model that automatically calculates a retaining wall model on a three-dimensional road model. The three-dimensional calculation device for a retaining wall model includes: a slope placement unit that places a slope model having a three-dimensional shape on the three-dimensional road model; an input unit that receives an input of an attribute of the retaining wall model; a calculation unit that calculates a three-dimensional intersection line of the slope model placed by the slope placement unit and the retaining wall model that is based on the attribute inputted to the input unit; and a display that displays information on the three-dimensional intersection line calculated by the calculation unit.

Specifically, the slope model placed on the three-dimensional road model has a three-dimensional shape, which makes a slope continuous in the horizontal direction and the direction of inclination. It is thus possible to obtain a continuous change of the shape of the slope. The retaining wall model based on the inputted attribute can also be used as a model continuous in the horizontal and vertical directions. Thus, the calculation unit can calculate the three-dimensional intersection line of the slope model and the retaining wall model as a continuous line. The three-dimensional intersection line represents the placement range of the retaining wall model and the shape of the retaining wall model, thereby making it possible to obtain the end position and shape change point of the retaining wall model continuously and precisely in three dimensions.

In another aspect of the present disclosure, the calculation unit can acquire a shape of a back surface of the retaining wall model based on the attribute inputted to the input unit and calculate a three-dimensional intersection line of the slope model and the back surface of the retaining wall model. In this case, the calculation unit can calculate a crown and a front surface of the retaining wall model based on the three-dimensional intersection line and the attribute inputted to the input unit. Thus, the specific shape of the retaining wall model can be calculated and provided to the user.

The calculation unit can also acquire the shape of the front surface of the retaining wall model that is based on the attribute inputted to the input unit and calculate a three-dimensional intersection line of the slope model and the front surface of the retaining wall model.

The input unit may be configured to receive an input of a first road alignment and a second road alignment that are different from each other. In this case, the slope placement unit places the slope model between the first road alignment and the second road alignment inputted to the input unit, and the calculation unit calculates the three-dimensional intersection line between the first road alignment and the second road alignment inputted to the input unit. In other words, precise calculation of the retaining wall model can be performed based on multiple road alignments.

When calculation of an intersection of the slope model and a flat embankment model between the first road alignment and the second road alignment inputted to the input unit is performed, and an end of the flat embankment model is detected, the calculation unit can determine that a retaining wall placement section for placing the retaining wall model is present and calculate the three-dimensional intersection line.

The input unit can receive an input of at least a shape of the retaining wall model and a method of placing the retaining wall model as the attribute of the retaining wall model. Further, an end of the three-dimensional intersection line calculated by the calculation unit is considered as an end of the retaining wall model, thereby making it possible to obtain the position of the end of the retaining wall model accurately.

According to a three-dimensional calculation program for a retaining wall model, it is possible to cause a computer to perform: a slope placement step of placing a slope model having a three-dimensional shape on the three-dimensional road model; an input step of receiving an input of an attribute of the retaining wall model; a calculation step of calculating a three-dimensional intersection line of the slope model placed in the slope placement step and the retaining wall model that is based on the attribute inputted in the input step; and a display step of displaying information on the three-dimensional intersection line calculated in the calculation step.

The present disclosure may also be directed to a three-dimensional calculation method for a retaining wall model that automatically calculates a retaining wall model on a three-dimensional road model. This method includes: a slope placement step of placing a slope model having a three-dimensional shape on the three-dimensional road model; an input step of receiving an input of an attribute of the retaining wall; a calculation step of calculating a three-dimensional intersection line of the slope model placed in the slope placement step and the retaining wall model that is based on the attribute inputted in the input step; and a display step of displaying information on the three-dimensional intersection line calculated in the calculation step.

As described above, calculation of a three-dimensional intersection line of a slope model and a retaining wall model allows precise calculation of an end position and a shape change point of the retaining wall model in three dimensions.

### BRIEF DESCRIPTION OF THE DRAWINGS

FIG. 1 is a configuration diagram of a three-dimensional calculation device for a retaining wall model of an embodiment of the present disclosure.

FIG. 2 is a block diagram of the three-dimensional calculation device for the retaining wall model.

FIG. 3 is a diagram showing an example of a three-dimensional road model.

FIG. 4 is a cross-sectional view taken along line IV-IV in FIG. 3.

FIG. 5 is a flowchart of a procedure for generating a three-dimensional road model.

FIG. 6 is a diagram showing an example of road alignment.

FIG. 7 is a diagram showing an example of a user interface screen for setting a road width.

FIG. 8 is a flowchart of procedures for three-dimensional calculation processing for a retaining wall model.

FIG. 9 is a perspective view showing part of a three-dimensional plane model.

FIGS. 10A to 10D are plan views of the three-dimensional road model shown in FIG. 9.

FIG. 11 is a diagram for explaining calculation of an intersection line of a slope model and a flat embankment model.

FIG. 12 is a diagram showing an example of a user interface screen for inputting a retaining wall shape.

FIG. 13 is a diagram showing an example of a user interface screen for inputting a method of embedding a retaining wall model.

FIG. 14 is a diagram for explaining embedding for embankment.

FIG. 15 is a diagram for explaining embedding for cutting.

FIG. 16 is a diagram for explaining embedding for cutting with an L-shaped water channel.

FIG. 17 is a diagram showing an example of a user interface screen for inputting a method of placing a retaining wall model.

FIG. 18 is a diagram for explaining direct placement of a retaining wall model on a protective shoulder.

FIG. 19 is a diagram for explaining placement of a retaining wall model with a specified height on an embankment model.

FIG. 20 is a diagram for explaining a case where a width from the road alignment center to an intersection point of the retaining wall model and the flat embankment model is specified.

FIG. 21 is a diagram for explaining a case where a retaining wall is placed on another road surface, while taking a slope length of the embankment and the width of a crown into account.

FIG. 22 is a diagram for explaining placement of a retaining wall with a specified height on a cut.

FIG. 23 is a diagram for explaining a case where a width from the road alignment center to the crown of the retaining wall is specified.

FIG. 24 is a diagram for explaining a case where the retaining wall is placed on an embankment from another road surface, while taking a slope length and a crown width into account.

FIG. 25 is a perspective view illustrating a calculation procedure of a three-dimensional intersection line of a slope model and a retaining wall model.

FIG. 26 is a cross-sectional view illustrating a calculation procedure of a three-dimensional intersection line of a slope model and a retaining wall model.

FIG. 27A is a cross-sectional view taken along line A-A in FIG. 9.

FIG. 27B is a cross-sectional view taken along line B-B in FIG. 9.

FIG. 27C is a cross-sectional view taken along line C-C in FIG. 9.

FIG. 28 is a plan view of a three-dimensional plane model.

FIG. 29 is a side view of a three-dimensional plane model.

### DETAILED DESCRIPTION

Embodiments of the present disclosure will be described in detail below with reference to the drawings. It should be noted that the following description of preferred embodiments is merely exemplary in nature and does not intend to limit the present disclosure or applications or use thereof.

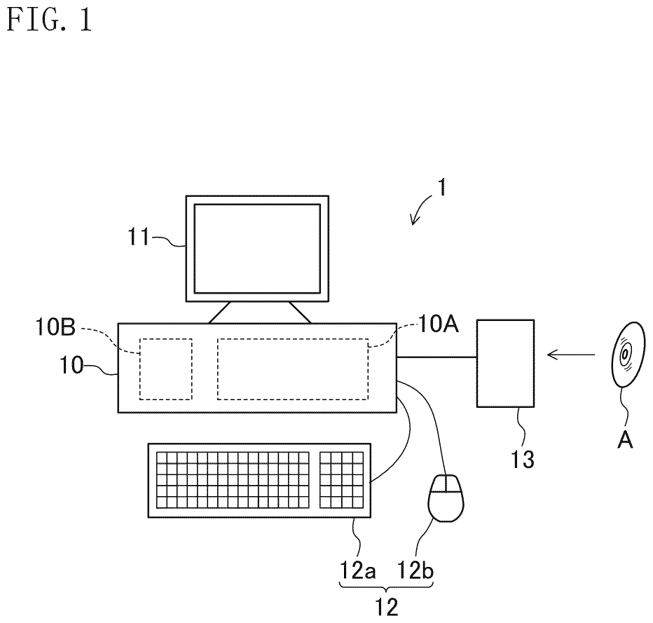

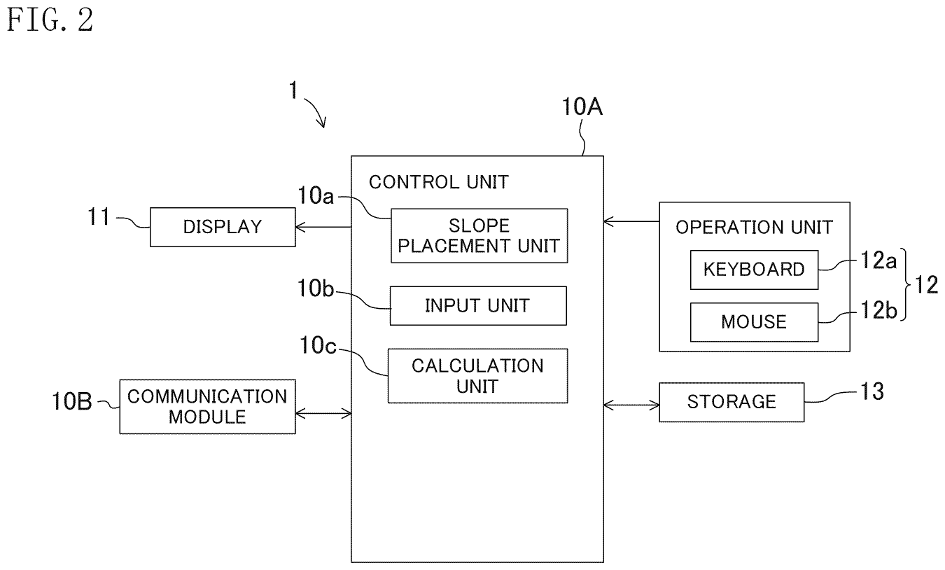

FIG. 1 is a diagram illustrating a configuration of a three-dimensional calculation device 1 for a retaining wall model of an embodiment of the present disclosure, and FIG. 2 is a block diagram of the three-dimensional calculation device 1 for the retaining wall model. The three-dimensional calculation device 1 for the retaining wall model is implemented by a personal computer and includes a body 10, a display 11, an operation unit 12, and a storage 13. The body 10 includes a control unit 10A and a communication module 10B. The control unit 10A includes, for example, a central processing unit (CPU), and a ROM and a RAM (memory) and operates according to a program. The memory is a work memory for developing a program for three-dimensional calculation of the retaining wall when the CPU executes the program, or a buffer memory for temporarily storing data. The communication module 10B communicates with external terminals via, for example, the Internet, and is configured to transmit and receive data.

The control unit 10A includes a slope placement unit 10a, an input unit 10b, a calculation unit 10c, etc., which will be described later. The slope placement unit 10a, the input unit 10b, and the calculation unit 10c may be implemented by the hardware constituting the control unit 10A alone or a combination of hardware and software. For example, when the CPU runs the three-dimensional calculation program, the control unit 10A can implement the functions of the slope placement unit 10a, the input unit 10b, and the calculation unit 10c.

The display 11 is implemented, for example, by a liquid crystal display device or an organic EL display device. The display 11 is connected to and controlled by the control unit 10A and is capable of displaying screens, such as various types of setting screens, an input screen, a design screen, and an analysis screen.

The operation unit 12 is implemented by a device handled by the user to operate the three-dimensional calculation device 1 for the retaining wall model. The operation unit 12 includes, for example, a keyboard 12a and a mouse 12b, and may also include a touch screen incorporated in the display 11 or various types of pointing devices. The operation unit 12 is connected to the control unit 10A so that a user's operation on the operation unit 12 can be detected by the control unit 10A.

The storage 13 is implemented by a hard disk drive or a solid-state drive capable of storing various data and programs. The storage 13 is connected to the control unit 10A and stores transmitted data and reads the stored data in accordance with an instruction from the control unit 10A. The storage 13 may be incorporated in the body 10 or may be provided outside the body 10. The storage 13 may be an external server or a so-called cloud storage system. Only part of the storage 13 may be incorporated in the body 10, and the other may be provided outside.

The storage 13 stores a three-dimensional calculation program for a retaining wall model that causes a computer to perform the steps described later. The three-dimensional calculation program for the retaining wall model may be provided to the user in any format. For example, as illustrated in FIG. 1, the user may be provided with a recording medium A, such as a CD-ROM or a DVD-ROM storing the program, or may download the program from an external server via the Internet. When the provided three-dimensional calculation program for the retaining wall model is installed in a general-purpose personal computer, the personal computer can be used as the three-dimensional calculation device 1 for the retaining wall model.

Installation of the three-dimensional calculation program for the retaining wall model in the general-purpose personal computer may be achieved by installing the program in the storage 13. When the general-purpose personal computer makes access to the external server in which the three-dimensional calculation program for the retaining wall model is installed, the personal computer can be used as the three-dimensional calculation device 1 for the retaining wall model. The three-dimensional calculation program for the retaining wall model can be installed in any location.

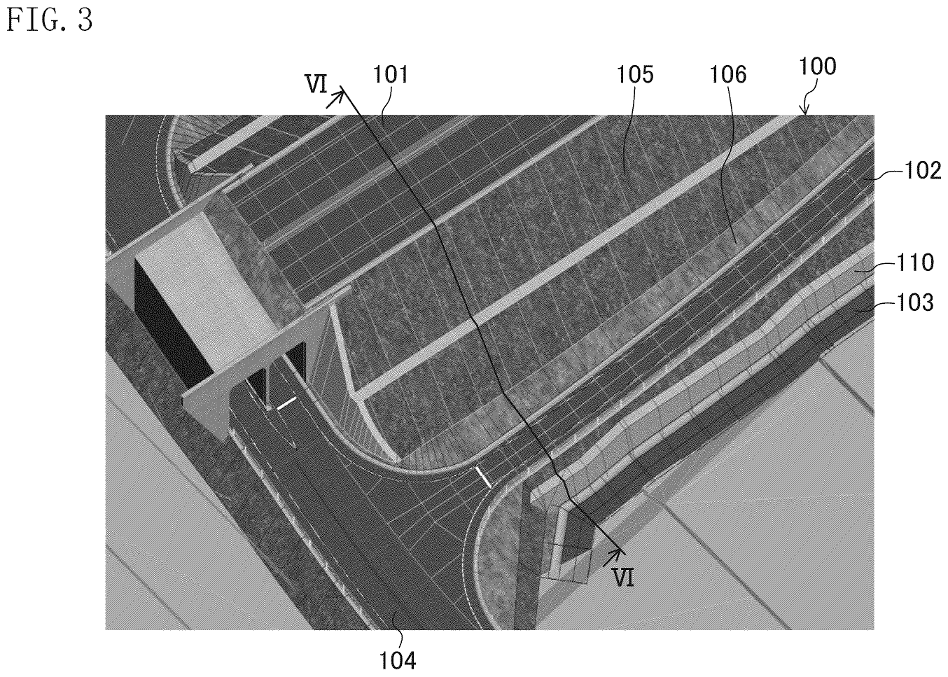

The three-dimensional calculation device 1 for the retaining wall model can create a three-dimensional road model 100 as shown in FIG. 3 as an example, by using software for supporting road design and performs processing for automatic calculation of a retaining wall model on the created three-dimensional road model 100. Data constituting the three-dimensional road model 100 is stored in, for example, the storage 13. The control unit 10A converts the data read from the storage 13 into an image representing the three-dimensional road model 100 as shown in FIG. 3 and shows the image on the display 11. Thus, the user can check the three-dimensional road model 100 on the display 11. The three-dimensional road model is represented by a color image.

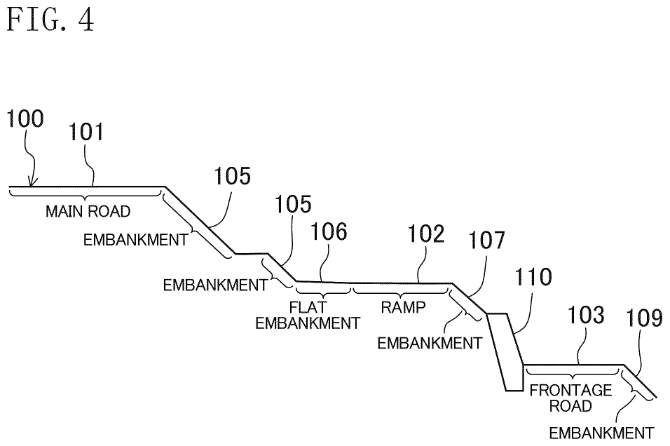

As shown in FIG. 4, the three-dimensional road model 100 includes a main road 101, a ramp (connecting road) 102, a frontage road 103, and an ordinary road 104. The main road 101 is a wide road such as an expressway. The ramp 102 is a road connecting the main road 101 and the ordinary road 104 and narrower than the main road 101. The part of the ramp 102 shown in FIG. 3 is located below the main road 101. The ramp 102 is ascending toward the junction with the main road 101 to approach the main road 101. The frontage road 103 is located below the ramp 102.

Since the ramp 102 is located below the main road 101, an embankment 105 is formed between the main road 101 and the ramp 102. A flat embankment (flat part) 106 is formed between the embankment 105 and the ramp 102. An embankment 107 and a retaining wall 110 are formed between the ramp 102 and the frontage road 103. An embankment 109 is formed on the side of the frontage road 103 opposite to the retaining wall 110.

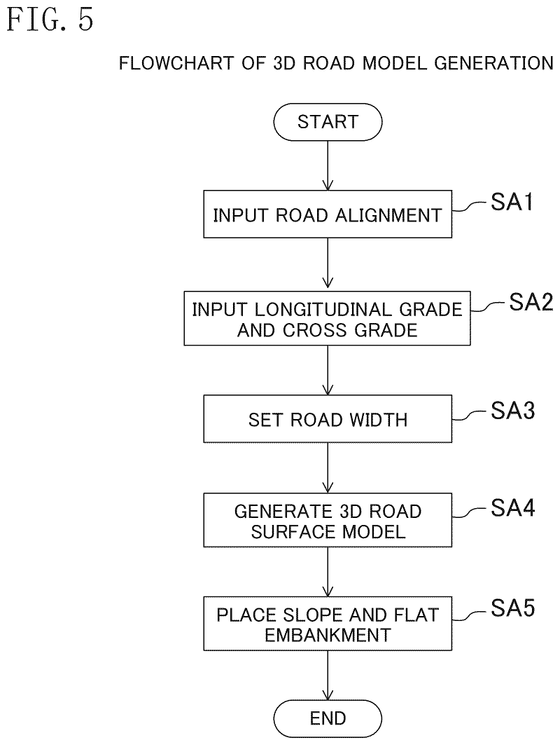

The three-dimensional road model 100 shown in FIG. 3 can be created using known computer-aided design (CAD) software for road design. Specifically, the three-dimensional road model 100 can be created through the procedures of the flowchart shown in FIG. 5 by using the three-dimensional calculation device 1 for the retaining wall model in which CAD software for road design is installed.

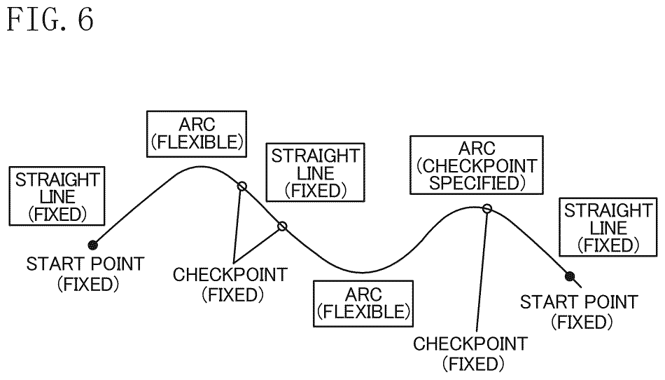

In Step SA1 after the start, the input of road alignment by the user is received. As shown in an example in FIG. 6, the road alignment is formed by a combination of elements, such as a straight line, an arc, and a clothoid curve, and has a fixed start point, a fixed end point, and fixed checkpoints between the start point and the end point that the road alignment should pass. The interval between the fixed points is formed by the combination of the elements.

When inputting the road alignment, the user operates the operation unit 12. The input unit 10b of the control unit 10A detects the operation made on the operation unit 12. The input unit 10b receives the input of the road alignment by detecting the operation on the operation unit 12. The example illustrated in FIG. 3 includes the main road 101, the ramp 102, and the frontage road 103; therefore, the input unit 10b receives the input of the road alignments of the main road 101, the ramp 102, and the frontage road 103. Specifically, the input unit 10b is configured to receive the input of a first road alignment and a second road alignment which are different from each other, thereby making it possible to create the three-dimensional road model 100 based on multiple road alignments.

In Step SA2, an input of a longitudinal grade and a cross grade by the user is received. The longitudinal grade and the cross grade may be inputted via a diagram of a longitudinal sectional shape and a diagram of a cross-sectional shape shown on a screen, or may be inputted by entering numerical values of the grades at different measurement points. In either technique, the input unit 10b receives the input of the longitudinal grade and the cross grade by detecting the operation on the operation unit 12.

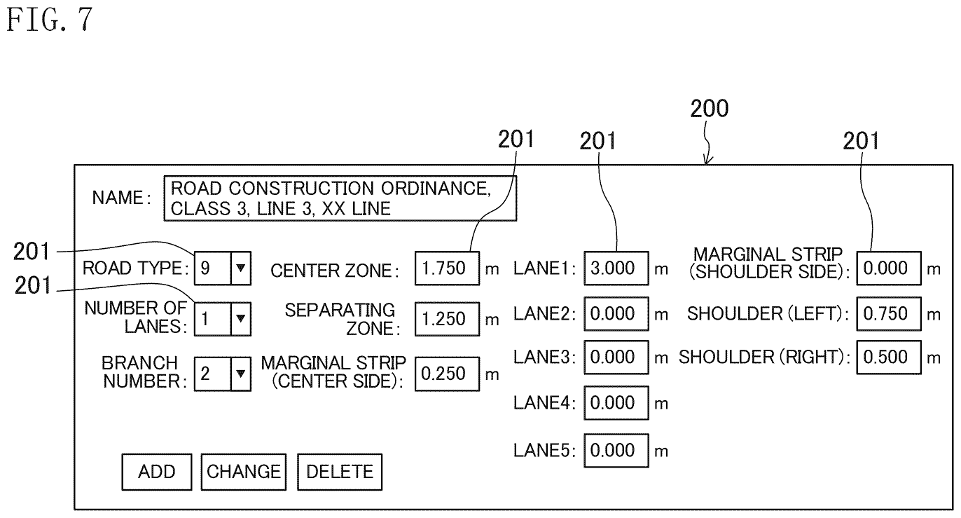

In Step SA3, setting of a road width by the user is received. The road width can be inputted using, for example, a user interface screen 200 for setting the road width shown in FIG. 7. The control unit 10A generates the user interface screen 200 for setting the road width and shows it on the display 11. The user interface screen 200 for setting the road width includes a plurality of input fields 201 that allow the user to separately input a road type, the number of lanes, a center zone, a separating zone, a marginal strip, the width of each lane, a shoulder width, etc. The user can enter any numerical value in each of the input fields 201 by operating the operation unit 12. The input unit 10b receives the input of the road width by detecting the operation on the operation unit 12 and sets the inputted road width.

In Step SA4, the calculation unit 10c creates a three-dimensional road surface model constituting the three-dimensional road model. The three-dimensional road surface model includes road surfaces of the main road 101, the ramp 102, and the frontage road 103 shown as a three-dimensional model.

In Step SA5, a three-dimensional model component in which a grade of a slope, a width of a berm, and a grade of a flat embankment are set is placed on each of the three-dimensional road surface models of the road alignments. Specifically, a point on the three-dimensional road surface model where a slope should be placed is specified, and an instruction is made to place the three-dimensional model of the slope on the specified point. Then, the slope placement unit 10a places a slope model having a three-dimensional shape at the specified point. In a case where the road alignment of the main road 101 is the first road alignment and the road alignment of the ramp 102 is the second road alignment, for example, the slope placement unit 10a places a slope model including the embankment 105 between the first road alignment and the second road alignment. Step SA5 is a slope placement step of placing a slope model having a three-dimensional shape on the three-dimensional road model. A berm model and a flat embankment model are placed in the same manner. Through the above-described steps, a three-dimensional road model where the slope model and the flat embankment model as shown in FIG. 3 are placed is created.

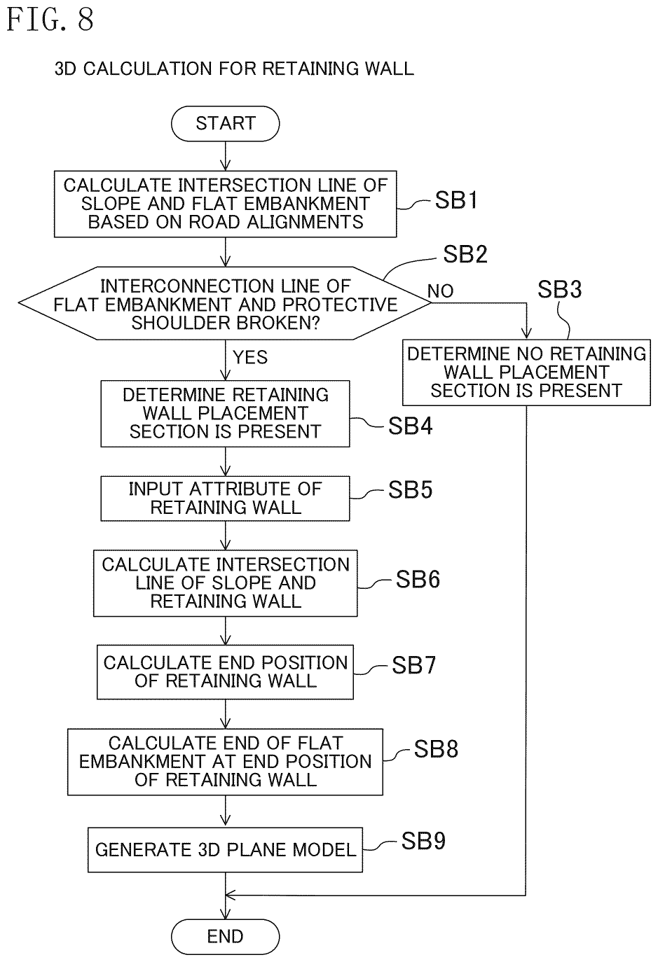

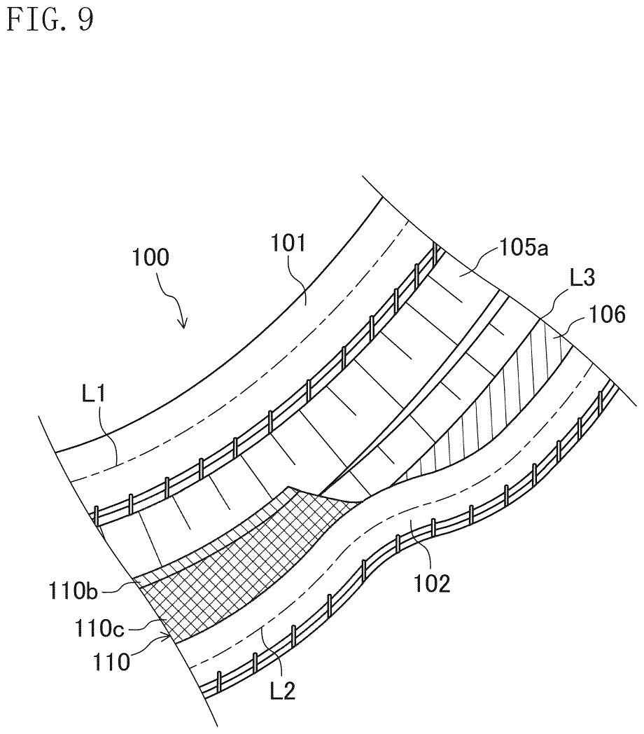

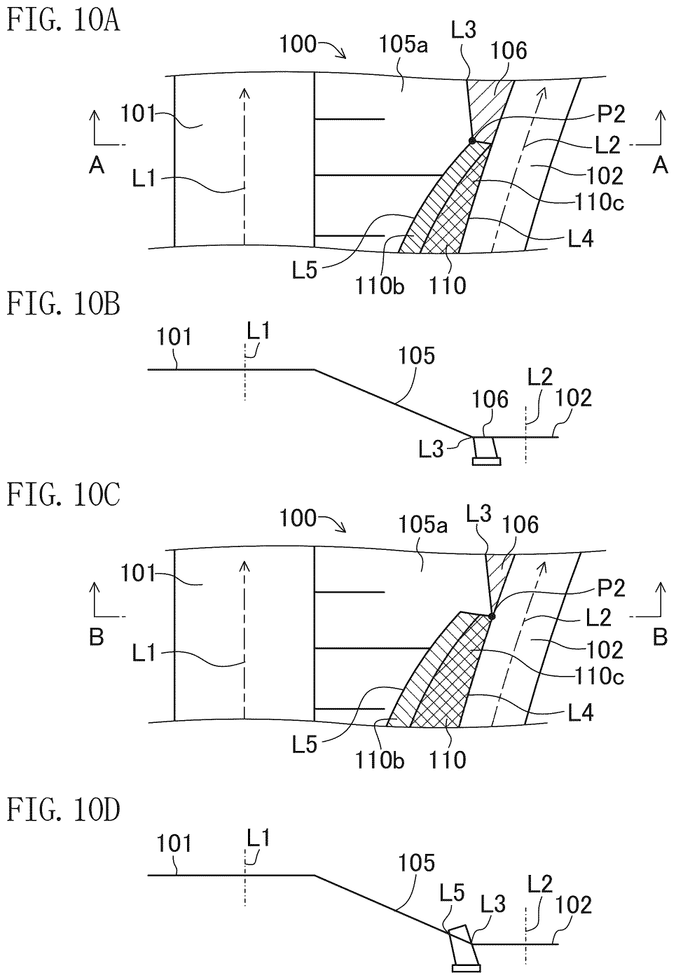

The three-dimensional calculation processing for the retaining wall will be described below with reference to the flowchart shown in FIG. 8. In Step SB1 after the start, the calculation unit 10c calculates an intersection line of a slope 105a and a flat embankment 106 formed by the embankment 105 between a road alignment L1 of the main road 101 and a road alignment L2 of the ramp 102 shown in FIG. 9. In this step, first, an embankment section and a cutting section are determined. Specifically, for each road alignment, the calculation of embankment and cutting is performed with respect to the current terrain to determine the embankment section and the cutting section. Then, calculation of an intersection line of the slope model and the flat embankment model between the road alignments is performed. Specifically, the flat embankment model is placed on the lower road surface in the embankment section and on the higher road surface in the cutting section, and the calculation of the intersection line with the slope model is performed. FIG. 9 shows a three-dimensional plane model that is generated in Step SB9, described later, and hence includes the retaining wall (retaining wall model) 110. However, the retaining wall 110 is not yet generated at the time of Step SB1. FIG. 10A is a plan view of the three-dimensional road model shown in FIG. 9, and FIG. 10B is a cross-sectional view taken along line A-A of FIG. 10A. FIG. 10C is a plan view showing a pattern of an end of the retaining wall model, and FIG. 10D is a cross-sectional view taken along line B-B of FIG. 10C.

First, it is determined whether a retaining wall placement section for placing the retaining wall model is present. Specifically, when the calculation of the intersection line of the slope (slope model) 105a and the flat embankment (flat embankment model) 106 between the road alignment L1 of the main road 101 and the road alignment L2 of the ramp 102 which are inputted to the input unit 10b is performed and an end of the flat embankment model 106 is detected, the retaining wall placement section is determined to be present. An example of this determination will be specifically described below.

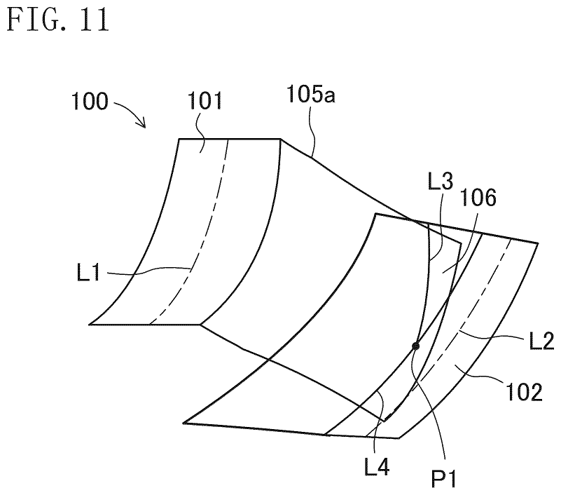

In Step SB1, whether the flat embankment 106 is to be placed on the higher side or the lower side of the slope 105a is specified, and an intersection line of the specified flat embankment 106 and the slope 105a is calculated. More specifically, as shown in FIG. 11, in the case where the flat embankment 106 is placed on the lower side of the slope 105a, the calculation unit 10c performs gradual intersection calculation to obtain an intersection line L3 of the slope 105a and the flat embankment 106.

In Step SB2, the calculation unit 10c determines whether there is a break in the intersection line of the flat embankment 106 and a protective shoulder. The protective shoulder mentioned in Step SB2 is a protective shoulder of the ramp 102. In FIG. 11, a reference character L4 indicates a line extending along the edge of the protective shoulder. When an intersection point P1 of the intersection line L3 and the line L4 is obtained, it is determined that the intersection line L3 is broken. When the intersection point P1 is not obtained, it is determined that the intersection line L3 is not broken, and the process proceeds to Step SB3. In Step SB3, it is determined that the retaining wall placement section for placing the retaining wall model is not present, and the process ends.

On the other hand, when the intersection point P1 is obtained and a break in the intersection line L3 is determined to be present, the process proceeds to Step SB4, and the calculation unit 10c determines that the retaining wall placement section is present. In Step SB5, the user inputs attributes of the retaining wall model. The attributes of the retaining wall model include a shape of the retaining wall model, a method of embedding the retaining wall model, and a method of placing the retaining wall model. Thus, the input unit 10b receives the inputs of the shape of the retaining wall model, the method of embedding the retaining wall model, and the method of placing the retaining wall model as the attributes of the retaining wall model. This will be specifically described below.

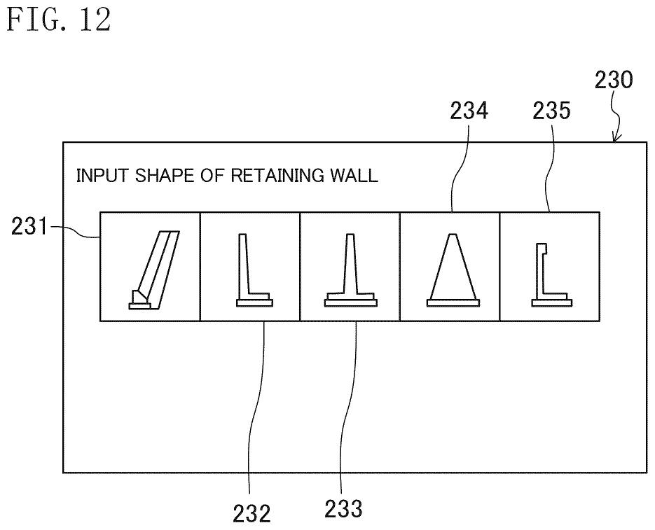

The user can input the shape of the retaining wall by using, for example, a user interface screen 230 for the input of the retaining wall shape shown in FIG. 12. The control unit 10A generates the user interface screen 230 for the input of the retaining wall shape and shows it on the display 11. The user interface screen 230 for the input of the retaining wall shape includes first to fifth icons 231 to 235 each indicating the retaining wall shape. The first icon 231 represents a block retaining wall, the second icon 232 an L-shaped retaining wall, the third icon 233 an inverted T-shaped retaining wall, the fourth icon 234 a gravity retaining wall, and the fifth icon 235 a reinforced earth retaining wall. The input unit 10b detects which one of the first to fifth icons 231 to 235 is selected by the user operating the operation unit 12. By detecting the operation on the operation unit 12, the input unit 10b receives the input of the retaining wall shape selected by the user from among the block retaining wall, the L-shaped retaining wall, the inverted T-shaped retaining wall, the gravity retaining wall, and the reinforced earth retaining wall, and sets the inputted retaining wall shape. The number of choices of the retaining wall shapes is not limited to five shapes described above, and other retaining wall shapes may be inputted. A pull-down menu, for example, may be used in place of the icons for the input of the retaining wall shape.

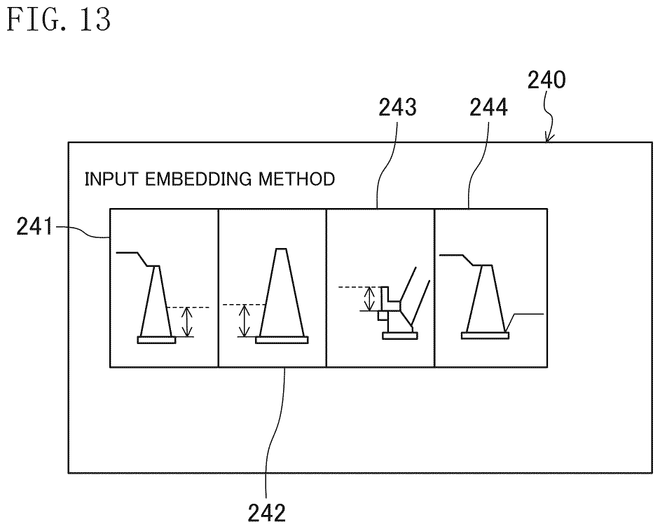

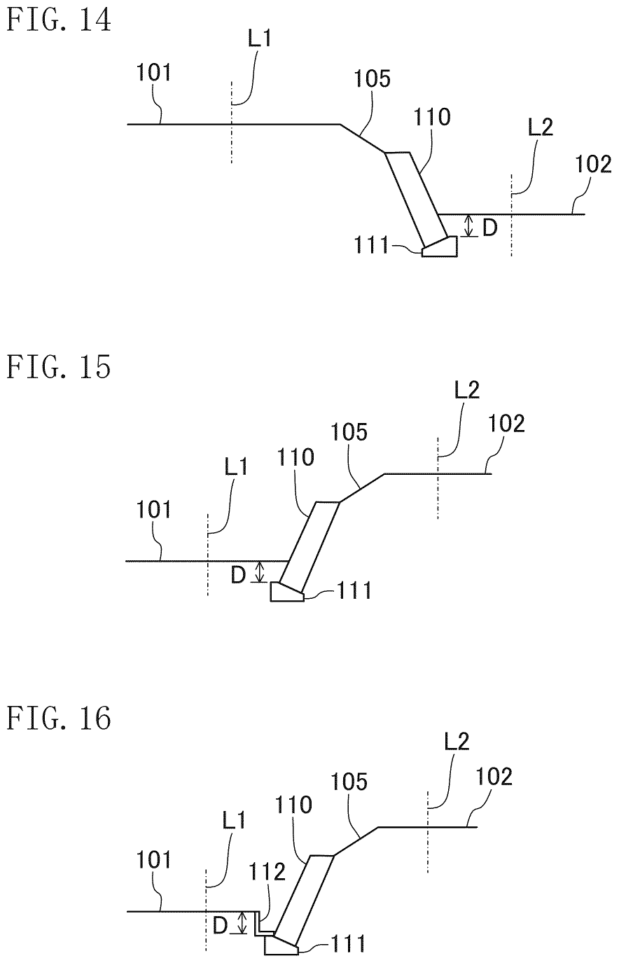

The user can input the method of embedding the retaining wall by using, for example, a user interface screen 240 for the input of the retaining wall embedding method shown in FIG. 13. The control unit 10A generates a user interface screen 240 for the input of the method of embedding the retaining wall and shows it on the display 11. The user interface screen 240 for the input of the method of embedding the retaining wall includes first to fourth icons 241 to 244 each indicating the retaining wall embedding method. The first icon 241 represents embedding for embankment. The embedding for embankment can be used when the main road 101 is located at a relatively high level as in the example of FIG. 14, and is shown with a foundation 111 and embedment depth D of the retaining wall 110.

The second icon 242 represents embedding for cutting. The embedding for cutting can be used when the main road 101 is located at a relatively low level as in the example of FIG. 15, and is shown with the foundation 111 and embedment depth D of the retaining wall 110. The third icon 243 represents a case in which an L-shaped water channel 112 is formed as shown in the example of FIG. 16. The fourth icon 244 represents a case in which not only the depth D but also the height can be specified in the embedding method.

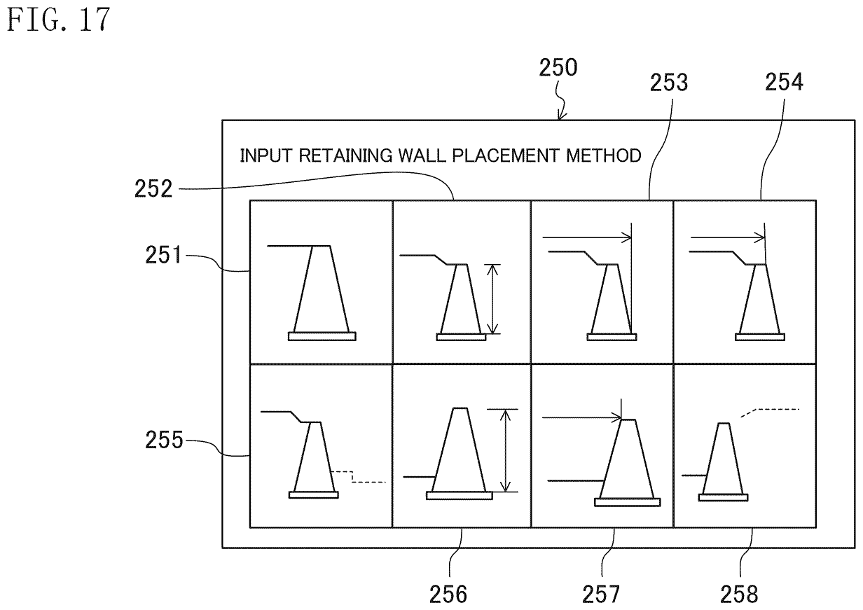

The user can input the method of placing the retaining wall model by using, for example, a user interface screen 250 for the input of the retaining wall model placing method shown in FIG. 17. The control unit 10A generates a user interface screen 250 for the input of the method of placing the retaining wall model and shows it on the display 11. The user interface screen 250 for the input of the method of placing the retaining wall includes first to eighth icons 251 to 258 each indicating the retaining wall model placing method.

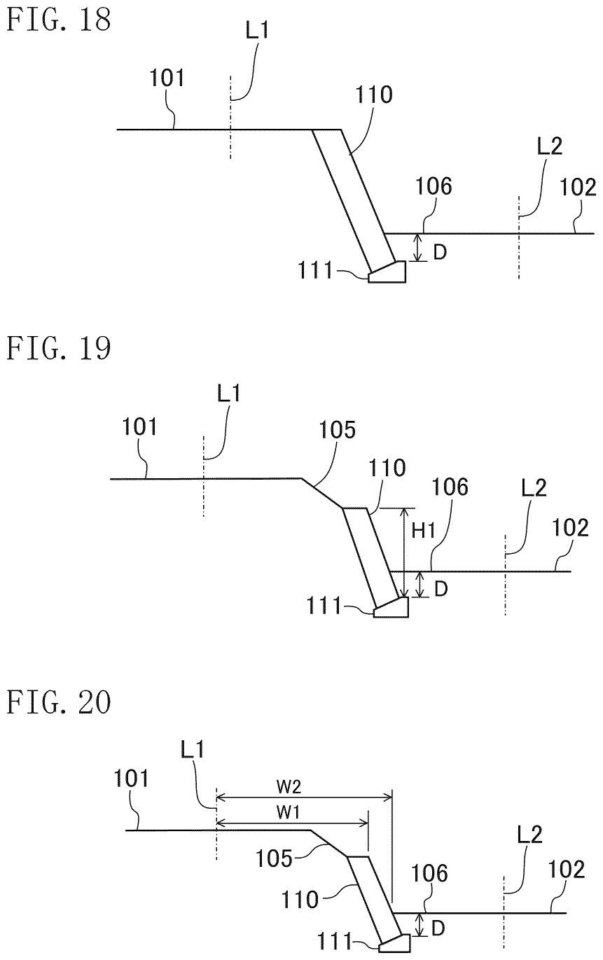

Each of the first to fifth icons 251 to 255 represents a type of placement on the embankment. The first icon 251 is selected when the retaining wall 110 needs to be placed directly at the protective shoulder. As shown in FIG. 18, the crown of the retaining wall 110 is placed directly at the road shoulder of the main road 101, and the position of the intersection point of the retaining wall 110 and the flat embankment 106 is calculated from the shoulder of the main road 101. The reference character D represents an embedment depth.

The second icon 252 is selected when the retaining wall model with a specified height needs to be placed on the embankment. The position of the intersection point with the embankment 105 is calculated from the height H1 of the retaining wall 110 and the embedment depth D as illustrated in FIG. 19.

The third icon 253 is selected in a case of specifying a width W2 from the road alignment center to the intersection point of the retaining wall model and the flat embankment model, and the fourth icon 254 is selected in a case of specifying a width W1 from the road alignment center to the crown of the retaining wall. As shown in FIG. 20, the position of the intersection point of the retaining wall 110 and the flat embankment 106 is calculated from the specified width W1 or W2.

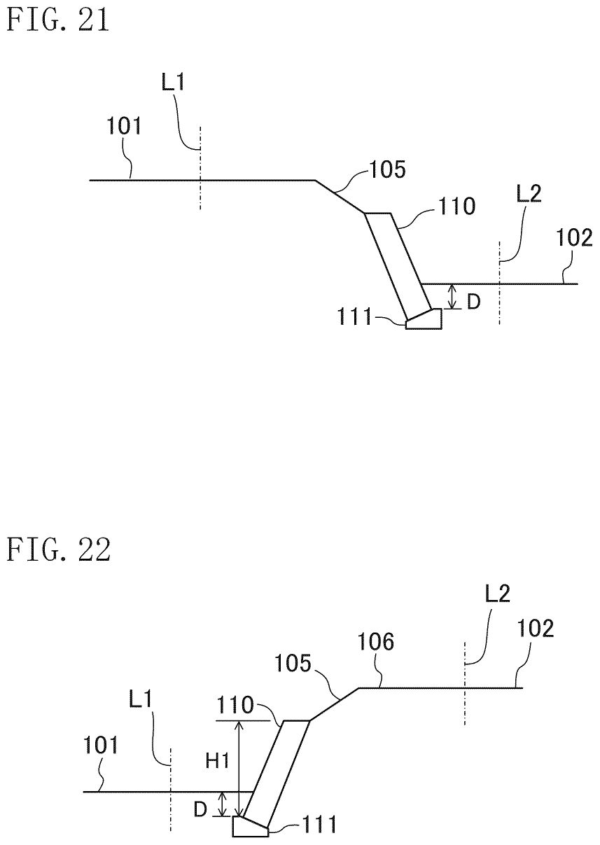

The fifth icon 255 is selected when the retaining wall needs to be placed on a different road surface, such as the frontage road, while taking the slope length of the embankment and the width of the crown into account. As shown in FIG. 21, the position of the intersection point of the retaining wall 110 and the embankment 105 is calculated from the shoulder of the ramp (frontage road) 102.

Each of the sixth to eighth icons 256 to 258 represents a type of placement on the cut. The sixth icon 256 is selected when the retaining wall with the specified height needs to be placed, and as shown in FIG. 22, the position of the intersection point of the embankment 105 and the flat embankment 106 is calculated for the retaining wall 110 with the specified height H1 from the shoulder of the main road 101.

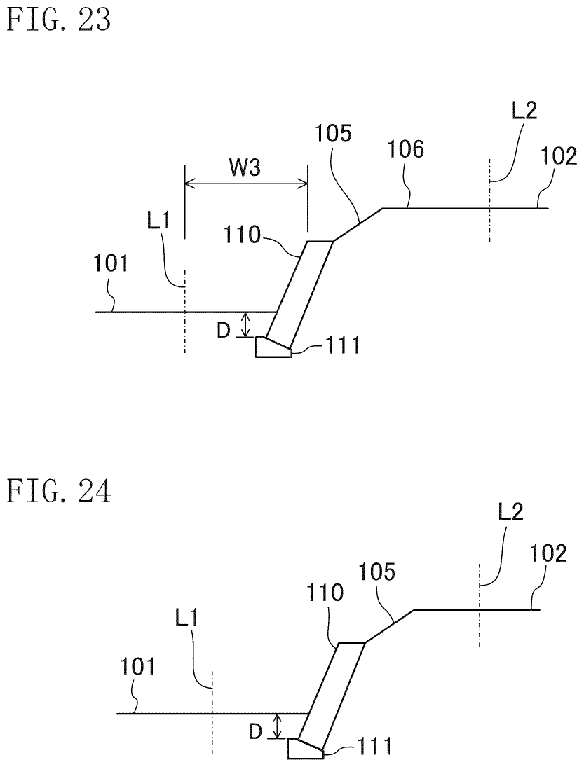

The seventh icon 257 is selected in a case of specifying the width from the road alignment center to the crown of the retaining wall. As shown in FIG. 23, the position of the intersection point of the embankment 105 and the flat embankment 106 is calculated for the retaining wall 110 with the specified width W3 from the center of the main road 101 to the crown.

The eighth icon 258 is selected when the retaining wall needs to be placed on the embankment from a different road surface, while taking the slope length and the crown width into account. As shown in FIG. 24, the position of the intersection point of the retaining wall 110 and the embankment 105 is calculated from the shoulder of the main road 101.

As described above, Step SB5 of the flowchart shown in FIG. 8 is performed. Step SB5 is an input step of receiving an input of attributes of the retaining wall model. After the input step, the process proceeds to Step SB6.

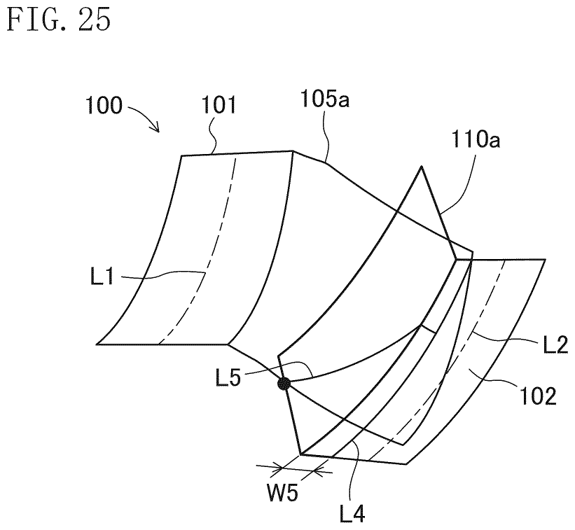

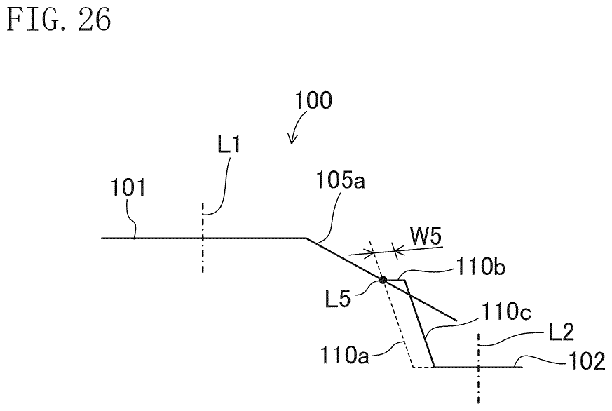

In Step SB6, the calculation unit 10c calculates a three-dimensional intersection line of the slope model placed on the three-dimensional road model by the slope placement unit 10a in the slope placement step and the retaining wall model that is based on the attributes inputted to the input unit 10b in the input step. Specifically, as shown in FIGS. 25 and 26, the calculation unit 10c acquires the shape of a back surface 110a of the retaining wall model based on the attributes inputted to the input unit 10b. Then, the calculation unit 10c obtains a three-dimensional intersection line L5 of the slope 105a and the back surface 110a of the retaining wall model by gradual intersection calculation between the road alignment L1 of the main road 101 and the road alignment L2 of the ramp 102 that are inputted to the input unit 10b. That is, not the front surface 110c of the retaining wall model (shown in FIG. 26) but the back surface 110a of the retaining wall model is used as a reference in obtaining the three-dimensional intersection line L5. It is thus possible to calculate the target three-dimensional intersection line L5 continuously in the extending direction of the road.

The calculation unit 10c may acquire the shape of a front surface of the retaining wall model based on the attribute inputted to the input unit 10b. In this case, the calculation unit 10c can obtain the three-dimensional intersection line of the slope 105a and the front surface of the retaining wall model by gradual intersection calculation between the road alignment L1 of the main road 101 and the road alignment L2 of the ramp 102 that are inputted to the input unit 10b.

The calculation unit 10c also calculates a crown 110b and the front surface 110c of the retaining wall 110 based on the three-dimensional intersection line L5 and the attributes inputted to the input unit 10b. When the three-dimensional intersection line L5 is obtained, the crown 110b is determined to extend in a range of the width W5 from the three-dimensional intersection line L5, and the surface extending downward from the front end of the crown 110b is determined to be the front surface 110c. The position of a lower end of the front surface 110c can also be determined.

After the calculation step of Step SB6, the process proceeds to Step SB7, and the calculation unit 10c calculates a point where the retaining wall model discontinues, i.e., a position of an end of the retaining wall model. Specifically, as shown in FIG. 10, the calculation unit 10c obtains an intersection point P2 of the flat embankment 106 and the three-dimensional intersection line L5. The intersection point P2 is the position of the end of the retaining wall model. It is also possible to perform the calculation between the slopes, for example, between the embankment model and the embankment model, by replacing the flat embankment model with the embankment model.

Thereafter, in Step SB8, the calculation unit 10c calculates the end of the flat embankment 106 at the end position of the retaining wall model obtained in Step SB7. The end of the flat embankment 106 is located at the intersection point P2 of the flat embankment 106 and the three-dimensional intersection line L5. In this step, first, processing related to the end of the retaining wall is specified. For example, the selection of either one of the following patterns is received: a case of calculating the end of the flat embankment at the end position of the retaining wall as shown in FIGS. 10A and 10B (pattern A); and a case of calculating the end of the retaining wall at the end position of the flat embankment as shown in FIGS. 10C and 10D (pattern B). When the pattern A is selected, the end of the flat embankment is calculated at the end position of the retaining wall. When the pattern B is selected, the end of the retaining wall is calculated at the end position of the flat embankment.

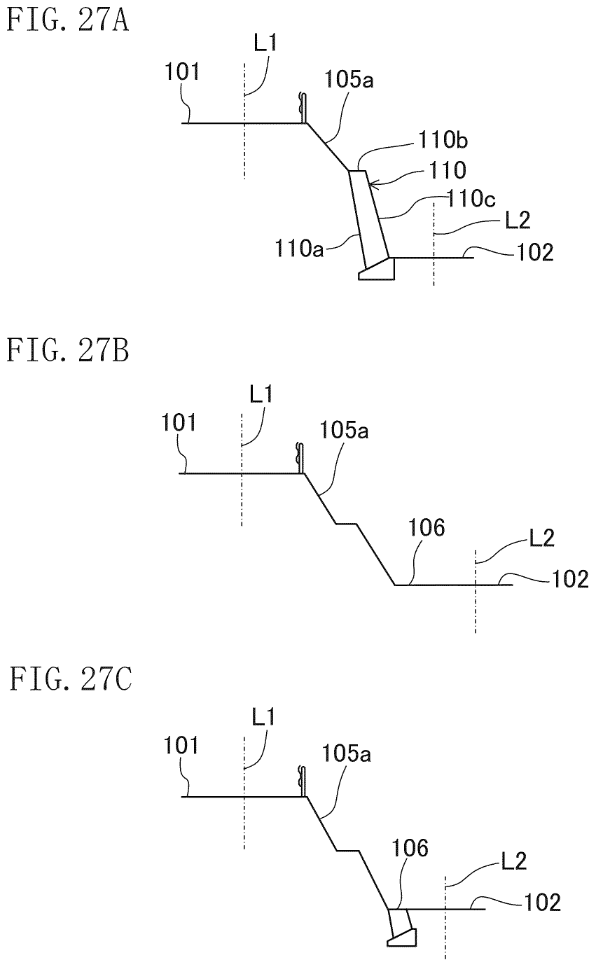

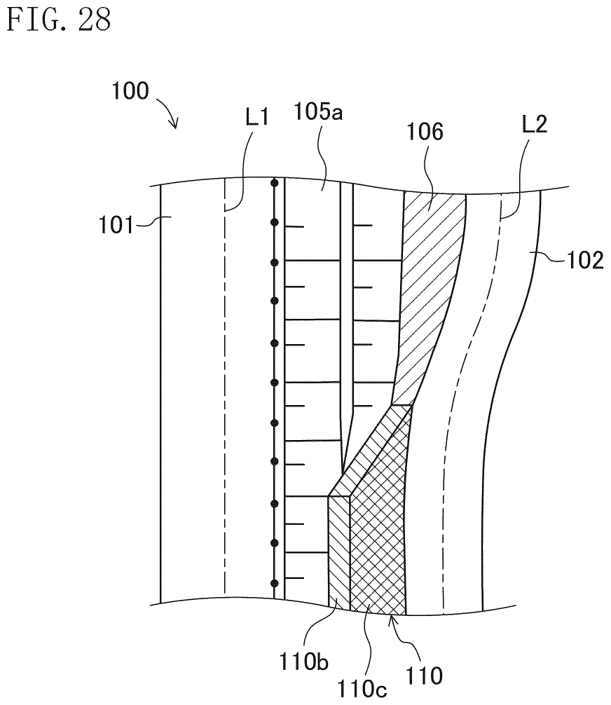

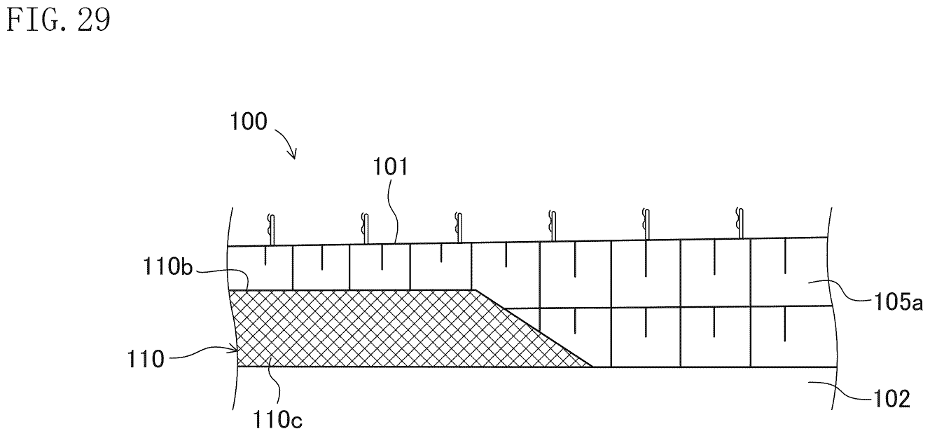

In Step SB9, a three-dimensional plane model is created. Examples of the three-dimensional plane model include models, such as a model shown as a perspective view in FIG. 9, models shown as cross-sectional views in FIGS. 27A, 27B, and 27C, a model shown as a plan view in FIG. 28, and a model shown as a side view in FIG. 29.

The information on the three-dimensional intersection line L5 calculated by the calculation unit 10c is displayed on the display 11. The three-dimensional plane model generated in Step SB9 includes the retaining wall 110 that is placed based on the three-dimensional intersection line L5, which means that the three-dimensional plane model also includes information on the three-dimensional intersection line L5. Accordingly, the information on the three-dimensional intersection line L5 is displayed on the display 11 by displaying the three-dimensional plane model on the display 11. For example, the three-dimensional intersection line L5 may be displayed on the display 11 as shown in FIG. 10. This step is a display step of displaying information on the three-dimensional intersection line L5 calculated in the calculation step.

As described above, the three-dimensional calculation program for the retaining wall model causes a computer to perform: a slope placement step of placing a slope model having a three-dimensional shape on a three-dimensional road model; an input step of receiving an input of an attribute of the retaining wall model; a calculation step of calculating a three-dimensional intersection line of the slope model placed in the slope placement step and the retaining wall model that is based on the attribute inputted in the input step; and a display step of displaying information on the three-dimensional intersection line calculated in the calculation step. The use of the three-dimensional calculation device 1 for the retaining wall model allows a three-dimensional calculation method for a retaining wall model including a slope placement step, an input step, a calculation step, and a display step.

### ADVANTAGES OF EMBODIMENT

According to this embodiment, the slope model can be placed at a desired position on the three-dimensional road surface model, and the slope model has a three-dimensional shape, which makes a slope continuous in the horizontal direction and the direction of inclination. It is thus possible to obtain a continuous change of the shape of the slope. The retaining wall model based on the attributes inputted in Step SB5 can also be used as a model continuous in the horizontal and vertical directions. Thus, as shown in FIG. 10 and other drawings, the calculation unit 10c can calculate the three-dimensional intersection line L5 of the slope 105a and the retaining wall 110 as a continuous line extending in the extending direction of the road. The three-dimensional intersection line L5 represents the placement range of the retaining wall 110 and the shape of the retaining wall 110, thereby making it possible to obtain the end position and shape change point of the retaining wall 110 precisely in three dimensions. Thus, the user can prepare a precise development of the retaining wall and can obtain the exact quantities of required concrete and other ingredients in the design phase.

The above-described embodiments are merely examples in all respects and should not be interpreted as limiting. All modifications and changes belonging to the equivalent scope of the claims are included in the scope of the present disclosure.

As can be seen in the foregoing description, the device and program for three-dimensional calculation of a retaining wall of the present disclosure can be used for, for example, a road design CAD system.

What is claimed is:

1. A three-dimensional calculation device for a retaining wall model that automatically calculates a retaining wall model on a three-dimensional road model, the device comprising:
a slope placement unit that places a slope model having a three-dimensional shape on the three-dimensional road model;
an input unit that receives an input of an attribute of the retaining wall model;
a calculation unit that calculates a three-dimensional intersection line of the slope model placed by the slope placement unit and the retaining wall model that is based on the attribute inputted to the input unit; and
a display that displays information on the three-dimensional intersection line calculated by the calculation unit.

2. The device of claim 1, wherein
the calculation unit acquires a shape of a back surface of the retaining wall model based on the attribute inputted to the input unit and calculates a three-dimensional intersection line of the slope model and the back surface of the retaining wall model.

3. The device of claim 1, wherein
the calculation unit acquires a shape of a front surface of the retaining wall model based on the attribute inputted to the input unit and calculates a three-dimensional intersection line of the slope model and the front surface of the retaining wall model.

4. The device of claim 2, wherein the calculation unit calculates a crown and a front surface of the retaining wall model based on the three-dimensional intersection line and the attribute inputted to the input unit.

5. The device of claim 1, wherein
the input unit receives an input of a first road alignment and a second road alignment that are different from each other,
the slope placement unit places the slope model between the first road alignment and the second road alignment inputted to the input unit, and
the calculation unit calculates the three-dimensional intersection line between the first road alignment and the second road alignment inputted to the input unit.

6. The device of claim 5, wherein
when calculation of an intersection of the slope model and a flat embankment model between the first road alignment and the second road alignment inputted to the input unit is performed, and an end of the flat embankment model is detected, the calculation unit determines that a retaining wall placement section for placing the retaining wall model is present and calculates the three-dimensional intersection line.

7. The device of claim 1, wherein
the input unit receives an input of at least a shape of the retaining wall model and a method of placing the retaining wall model as the attribute of the retaining wall model.

8. The device of claim 1, wherein
an end of the three-dimensional intersection line calculated by the calculation unit is considered as an end of the retaining wall model.

9. A three-dimensional calculation program for a retaining wall that automatically calculates a retaining wall model on a three-dimensional road model, the program causing a computer to perform:
a slope placement step of placing a slope model having a three-dimensional shape on the three-dimensional road model;
an input step of receiving an input of an attribute of the retaining wall model;
a calculation step of calculating a three-dimensional intersection line of the slope model placed in the slope placement step and the retaining wall model that is based on the attribute inputted in the input step; and
a display step of displaying information on the three-dimensional intersection line calculated in the calculation step.
